(19) United States
(12) Patent Application Publication
(10) Pub. No.: US 2021/0151396 A1
(43) Pub. Date: May 20, 2021

(54) SEMICONDUCTOR CHIP FOR RF SIGNAL AMPLIFICATION (As Amended)

(71) Applicant: SUMITOMO ELECTRIC INDUSTRIES, LTD., Osaka (JP)

(72) Inventors: Mikoto NAKAMURA, Yokohama-shi (JP); Takeshi KAWASAKI, Yokohama-shi (JP)

(73) Assignee: SUMITOMO ELECTRIC INDUSTRIES, LTD., Osaka (JP)

(21) Appl. No.: 17/105,492

(22) Filed: Nov. 25, 2020

Related U.S. Application Data
(63) Continuation of application No. 15/797,944, filed on Oct. 30, 2017.

(30) Foreign Application Priority Data
Oct. 31, 2016 (JP) 2016-213399

(51) Int. Cl. H01L 23/66; H01L 23/528; H01L 23/00; H01P 3/08; H03F 3/195

(52) U.S. Cl. CPC H01L 23/66; H01L 23/528; H01P 5/028; H01P 3/081; H03F 3/195; H01L 24/16

(57) ABSTRACT

A radio-frequency (RF) apparatus that reduces signal reflections at input and output terminals includes a semiconductor chip mounted on an assembly base upside down. The semiconductor chip includes first to third metal layers and a top metal layer that provides a top ground layer and a pad. The pad is connected to the input or output terminals on the assembly base and extracts a signal line and a stub line in the third metal layer. The semiconductor chip further includes an inner ground layer formed in the second metal layer. The inner ground layer and the signal line pulled out from the pad and formed in the third metal layer form a micro-strip line.

### CROSS-REFERENCE TO RELATED APPLICATIONS

This application is a continuation of and claims priority from U.S. application Ser. No. 15/797,944 filed on Oct. 30, 2017, which claims priority from Japanese Application 2016-213399 filed on Oct. 31, 2016, both applications being incorporated by reference herein.

### BACKGROUND OF THE INVENTION

### 1. Field of the Invention

The present invention relates to a semiconductor electronic device operable in radio frequencies (RFs), in particular, the invention relates to an electronic device having transmission lines.

An RF apparatus usually implements transmission lines, such as micro-strip line, to carry high frequency signals. Transmission lines within the RF apparatus may be connected with external devices through pads, and those pads are connected with the external devices through bonding wires, bumps, and the like. One type of electronic devices has developed and become popular in the field, in which a circuit board mounts amplifiers capable of outputting high power, which is called as a power amplifier module.

The transmission lines are usually matched in impedance thereof with that of units or blocks connected thereto, while, pads in an end of a transmission line is not matched or unable to be matched in impedance thereof with those units or blocks, which results in a reflection of high frequency signals at the pads. In particular, reflection of a signal becomes extreme in high frequencies of microwaves and millimeter waves.

### SUMMARY OF THE INVENTION

An aspect of the present invention relates to a radio frequency (RF) apparatus that amplifies an RF signal. The RF apparatus of the invention includes a semiconductor chip and an assembly base that mounts the semiconductor chip thereon in upside down arrangement of a ball grid array. The semiconductor chip includes a semiconductor substrate, first to third metal layers, a top metal layer, a signal line, and a stub line. The semiconductor substrate includes a semiconductor active device therein. The first to third metal layers are stacked on the semiconductor substrate in this order and electrically isolated to each other by an insulating layer. The top metal layer, which is provided on a top surface of the insulating layer, includes a top ground layer and a pad that is electrically isolated from the top ground layer by a gap. The pad is connected with the assembly base through a solder ball of the ball grid array. The signal line carries the RF signal to the semiconductor active device or extracts the RF signal from the semiconductor active device. The stub line, which is also connected to the pad, has a length shorter than λ/4, where λ is a wavelength of the RF signal. A feature of the RF apparatus of the present embodiment is that the inner ground layer overlaps with the gap between the pad and the top ground layer, thereby increasing capacitive components to the pad.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1A shows a cross section of a radio-frequency (RF) device according to the first embodiment of the present invention, FIG. 1B is a plan view of a semiconductor chip implemented in the RF apparatus shown in FIG. 1A, which is viewed from a side of a solder bump, and FIG. 1C is a plan view showing an assembly base also viewed from the solder bump;

FIG. 2A shows a cross section of the semiconductor chip taken along the line IIA-IIA indicated in FIG. 1B, and FIG. 2B shows a cross section of the semiconductor ship taken along the line IIB-IIB also indicated in FIG. 1B;

FIG. 3A shows behaviors of an S-parameter S₁₁ viewed from the signal line on the assembly substrate, and FIG. 3B shows the smith chart of the S-parameter S₁₁ shown in FIG. 3A;

FIG. 4A shows a cross section of an RF apparatus modified from that shown in FIG. 1A, and FIG. 4B is a plan view of a semiconductor chip implemented within the RF apparatus shown in FIG. 4A;

FIGS. 5A and 5B are plan views showing semiconductor chips modified from that shown in FIG. 1A;

FIGS. 6A and 6B are plan views of the semiconductor chips according to the second embodiment and a modification thereof;

FIG. 7A shows a cross section of an RF apparatus that implements a semiconductor chip according to the third embodiment of the present invention, and FIG. 7B is a plan view showing the semiconductor chip implemented within the RF apparatus shown in FIG. 7A; and

FIG. 8A is a plan view showing an RF apparatus according to the fourth embodiment and FIG. 8B shows a cross section of the RF apparatus providing the semiconductor chip and the assembly substrate.

### DESCRIPTION OF EMBODIMENT

Next, embodiment according to the present invention will be described as referring to accompanying drawings. In the description of the drawings, numerals or symbols same with or similar to each other will refer to elements same with or similar to each other without duplicating explanations.

### First Embodiment

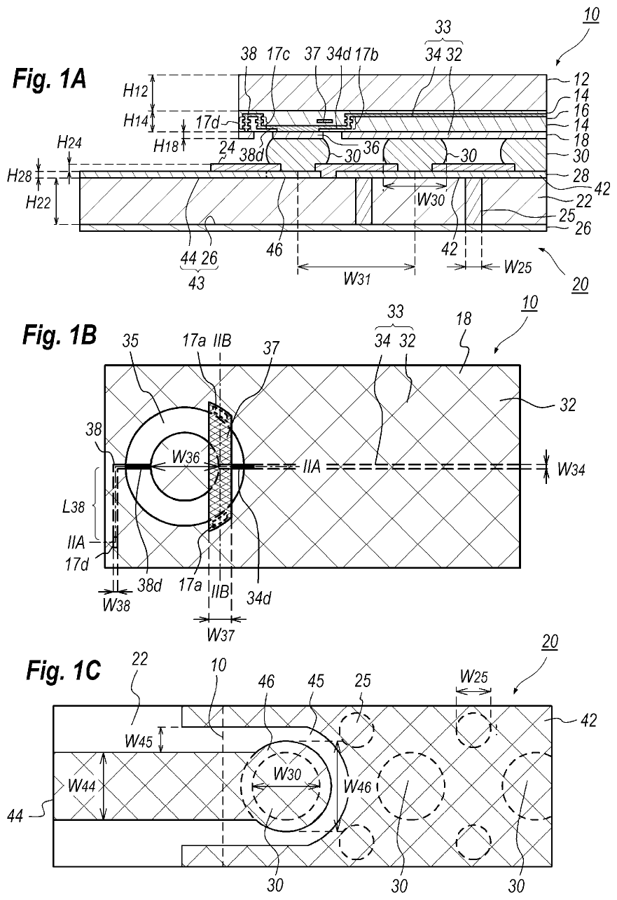

FIG. 1A shows a cross section of a radio-frequency (RF) apparatus according to the first embodiment of the present invention, FIG. 1B is a plan view of a semiconductor chip implemented in the RF apparatus, which is viewed from a side of a solder bump, and FIG. 1C is a plan view showing an assembly base also viewed from the solder bump.

The semiconductor chip 10 of the present embodiment provides a semiconductor substrate 12 and an insulating layer 14 that buries a metal layer 16 therein, a top metal layer 18 in a top surface thereof, and a via 15 passing at least a portion of the insulating layer 14. The via 15, which is filled with a metal, connects the metal layer 16 with the top metal layer 18.

The metal layer 16 includes a signal line 34 that is connected with a semiconductor active device formed in the semiconductor substrate 12, which is not illustrated in FIGS. 1A and 1B. The top metal layer 18 includes a top ground layer 32 and a pad 36. The signal line 34 and the top ground layer 32 form a transmission line type of micro-strip line.

The metal layer 16 includes a stub line 38 whose one end is connected with the pad 36 through a stacked via 17c, while the other end is connected with the top ground layer 32 through another stacked via 17d. Thus, the stub line 38 also overlaps with the top ground layer 32 as interposing the insulating layer 14 therebetween.

The semiconductor chip 10 thus configured is mounted on an assembly base 20 that provides a substrate 22, a metal layer 28 on a top surface of the substrate 22 and a ground layer 26 in a back surface of the substrate 22. The metal layer 28 includes a ground layer 42, a pad 46, and a signal line 44. The assembly base 20 further provides vias 25 each filled with a metal, where the vias 25 electrically connect the ground layer 42 on the top surface of the substrate 22 with the ground layer 26 in the back surface. The metal layer 28 on the top surface is protected with a cover layer 24. The signal line 44 forms a transmission line 43 type of micro-strip line by overlapping with the ground layer 26 in the back surface of the substrate 22.

Referring to FIG. 1B, where the signal line 34 is illustrated by broken lines, the semiconductor chip 10 provides the top ground layer 32 in the top surface thereof with the gap 35, within which the pad 36 is formed. Referring to FIG. 1C, broken lines denote the vias 25 and a trace of the semiconductor chip 10. The ground layer 42 in the top surface of the substrate 22 faces the top ground layer 32 in the top surface of the semiconductor chip 10. The ground layer 42 in the assembly base 20 provides a gap 45 that surrounds a pad 46. The signal line 44 is connected with the pad 46. The solder bumps 30 are formed between the pad 46 and the ground layer 42.

Symbols H₁₂ to H₂₈ appearing in FIGS. 1A to 1C correspond to thicknesses of the semiconductor substrate 12, the insulating layer 14, the top metal layer 18, the substrate 22, the cover lay 24, and the top metal layer 28, respectively. While, symbols, W₂₅ to W₄₆, correspond to widths of the vias 25, the bump 30, the signal line 34, the gap 35, the pad 36, the stub line 38, the signal line 44, the gap 45, and the pad 46, respectively. The symbols, W₃₁ and L₃₈, denote a pitch of the bumps and a length of the stub line 38.

A feature of the embodiment is that the semiconductor chip 10 provides an additional ground layer 37, which is denoted by a hatched area in FIG. 1B and may be called as an inner ground layer. The inner ground layer 37 overlaps with a portion of a signal line 34d in a gap 35 and also with a portion of a pad 36. The inner ground layer 37 is connected with a top ground layer 32 through a stacked vias 17d in respective sides. The specification assumes that the inner ground layer 37 has a width W₃₇.

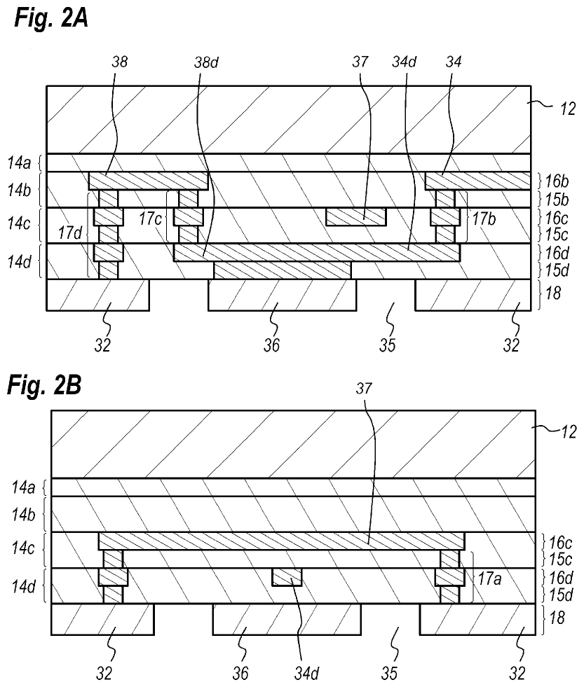

FIG. 2A shows a cross section of the semiconductor chip 10 taken along the line indicated in FIG. 1B, and FIG. 2C also shows a cross section of the semiconductor chip 10 taken along the line IIB-IIB indicated in FIG. 1B. The insulating layer 14 stacks several insulating layers, 14a to 14d, where the insulating layer 14a is sometimes called as a passivation layer that protects a surface of the semiconductor substrate 12. The insulating layers, 14a to 14d, provide metal layers, 16a and 16d, and via metals, 15b to 15d, therein, where figures omit the metal layer 16a. The specification below calls the insulating layer 14b, the via metal 15b, and the metal layer 16b as the first insulating layer, the first via metal, and the first metal layer; those elements, 14c, 15c, and 16c, are second one; and those elements 14d, 15d, and 16d, are third one, respectively. The third insulating layer 14d on a top surface thereof provides the top metal layer 18 thereon.

The first metal layer 16b includes the signal line 34 and the stub line 38. The second metal layer 16c includes the inner ground layer 37, the third metal layer 16d includes the signal line 34d and the stub line 38d that is pulled out from the pad 36. The stacked via 17b connects the signal line 34 in the first metal layer 16b with the signal line 34d in the third metal layer 16d; the stacked via 17d connects the stub line 38 in an end thereof with the stub line 38d; the stacked via 17c connects the stub line 38d pulled out from the pad 36 with an end of the stub line 38 in the first metal layer 16b; and the stacked via 17d connects the other end of the stub line 38 with the top ground layer 32. The stacked vias, 17b and 17c, include the first and second via metals, 15b and 15c, and the second metal layer 16c; while, the stacked via 17d includes the first to third via metals, 15b to 15d, and the second and third metal layers, 16c and 16d. The inner ground layer 37 overlaps with the signal line 34d and the pad 36 as interposing the insulating layer 14c therebetween.

As FIG. 2B illustrates, the second metal layer 16c includes the inner ground layer 37. The third metal layer 16d includes the signal line 34d. The inner ground layer 37 is connected with the top ground layer 32 in respective sides of the gap 35 through the stacked vias 17a that includes the second and third via metals, 15b and 15c, and the third metal layer 16c. The inner ground layer 37 crosses the signal line 34d as interposing the second insulating layer 14c therebetween.

The stub line 38, which overlaps with the top ground layer 32, is connected in on end thereof with the pad 36 through the stacked via 17c and the other end thereof is connected with the top ground layer 32 through the stacked via 17d. Thus, the stub line 38 operates as a short stub. Because the stacked vias, 17c and 17d, are short enough compared with the length of the stub line 38, the short stub thus configured has the length substantially equal to the length of the stub line 38, and the stub line 38 in the length thereof is set to be shorter than λ/4, where λ is a wavelength of an RF signal subject to the present RF apparatus. Thus, the stub line 38 may be regarded as an inductor for the RF signal. Assuming that the pad 36 causes parasitic capacitance of Cpad against the top ground layer 32 and the stub line 38 has inductance of Lstub, total capacitance Ctotal of the pad 36 against the top ground layer 32 becomes:

Ctotal=Cpad−1/(ω²×Lstub).

Accordingly, the total capacitance viewed from the pad 36 becomes variable depending on the length of the stub line 38. The stub line 38 may compensate impedance mismatch between the transmission line 33 and the pad 36.

Because the short stub is formed in the stub line 38 and the top ground layer 32; the adjustment of the length of the stub line 38 becomes simple compared with arrangements where a short stub is formed by the top metal layers, 18 and 28, on the semiconductor chip 10 and the assembly base 20. Gaps between the pads, 36 and 46, and the ground layers, 32 and 42, are unable to be optionally deter mined and substantially restricted from a process for forming the bump 30. That is, a preset space is inevitably secured around the bump 30, which means that a stub line is unable to be drawn directly from the pad, 35 or 45. When the stub line 38 is provided in one of the first to third metal layers, 16b to 16d, the stub line 38 may be placed close enough to the pad 36.

An S-parameter S₁₁ is evaluated for the arrangement of the RF apparatus according to the first embodiment shown in FIG. 1A. Dimensions of the arrangement and physical properties are listed in the following table:

| semiconductor chip 10 | | |
|---|---|---|
| semiconductor substrate 12 | GaAs thickness H₁₂: 250 μm | |
| insulating layer 14 | polyimide | dielectric constant ε: 3.5 |
| | | thickness H₁₄: 8 μm |
| top metal layer 18 | gold (Au) | thickness H₁₈: 2 μm |
| bump 30 | solder | thickness H₃₀: 300 μm |
| | | width W₃₀: 150 μm |
| | | pitch W₃₁: 400 μm |
| stub line 38 | | impedance: 50 ohm |
| | | width W₃₈: 10 μm |
| | | length L₃₈: 250 μm |
| inner ground layer 37 | | width W₃₇: 35 μm |
| assembly base 20 | | |
| substrate 22 | Teflon ® | thickness H₂₂: 101 μm |
| cover lay 24 | | thickness H₂₄: 30 μm |
| via 25 | copper (Cu) | width W₂₅: 100 μm |
| top metal layer 28 | copper (Cu) | thickness H₂₈: 30 μm |
| signal line 44 | copper (Cu) | impedance: 50 ohm |
| | | width W₄₄: 190 μm |
| gap 45 | | width W₄₅: 100 μm |
| pad 46 | | width W₄₆: 250 μm |

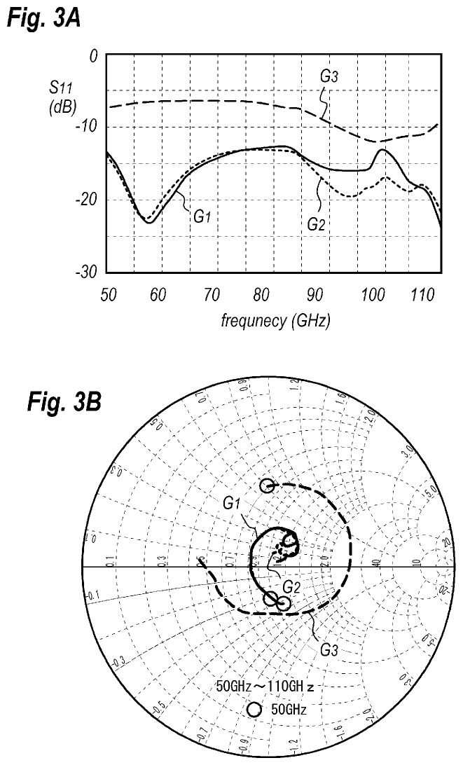

FIG. 3A shows behaviors of S₁₁ viewed from the signal line 44 on the assembly base 20, and FIG. 3B shows the smith chart of S₁₁ shown in FIG. 3A. The S₁₁ are evaluated for frequencies from 50 to 110 GHz. In FIGS. 3A and 3B, behaviors, G₁ to G₃, correspond to the arrangement of the present invention, the arrangement without any stub line, and the arrangement where the signal line 34 extracted from the pad 36 has a widened portion neighbor to the pad 36 but with no inner ground layer 37. The widened portion, which has a width of 100 μm and a length of 30 μm, may increase capacitance against the top ground layer 32 viewed from the pad 36. Instead, the stub line 38 is shortened to 60 μm from 250 μm.

As FIGS. 3A and 3B indicate, the S-parameter S₁₁ obtained in the present embodiment is comparable to the arrangement with the widened portion in the signal line because of the existence of the stub line 38 that substantially matches the input impedance of the RF apparatus viewed from the pad 46 in frequencies from 50 to 110 GHz. In particular, the stub line 38 of the present embodiment, behavior G₁, improves S₁₁ compared with the arrangement with the widened portion but without the inner ground layer 37, behavior G₂, in frequencies from 57 to 70 GHz.

According to the first embodiment, the inner ground layer 37, which is formed within in the insulating layer 14, overlaps with the signal line 34d in a portion of the gap 35, also with the pad 36 in a portion closer to the signal line 34. Accordingly, this arrangement between the pad 34 and the signal line 34d against the inner ground layer 37 may add additional capacitive components to the pad 36 and the signal line 34d, and improve the impedance matching between the transmission line 33 and the pad 36.

The inner ground layer 37 is connected with the top ground layer 32 in respective sides thereof that sandwiches the signal line 34d therebetween. This arrangement of the signal line 34d, the inner ground layer 37, and, as FIG. 2B illustrates, the stacked vias 17a may form pseud co-planar line around the gap 35, which may suppress degradation of the RF signal in high frequencies. The first metal layer 16b forms the signal line 34, the third metal layer 16c forms the signal line 34d, and the second metal layer 16c forms the inner ground layer 37, which enables the inner ground layer 37 to be formed closer to the signal line 34d and the pad 36; and the pad 36 may show increased parasitic capacitance in a side of the signal line 34.

The stub line 38 may have a length longer than λ/12 but shorter than 3λ/12 to suppress the reflection at the pad 36 and the bump 30. Or, further preferably, the stub line 38 has a length of λ/6, where λ is a wavelength of the RF signal subject to the RF apparatus of the invention. The stub line 38 is preferably formed in a side opposite to the signal line 34 with respect to the pad 36. Also, the stub line 38 preferably makes an angle greater than 90° against the signal line 34.

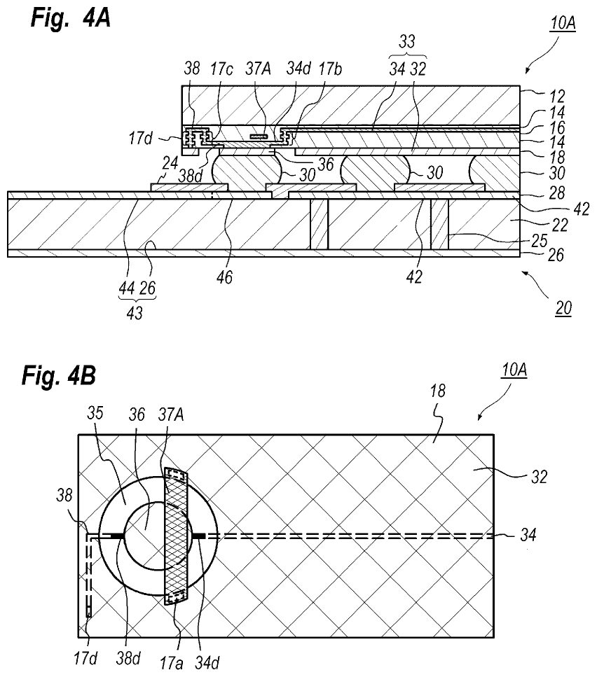

FIG. 4A shows a cross section of an RF apparatus modified from that shown in FIG. 1A, and FIG. 4B is a plan view of a semiconductor chip 10A implemented within the RF apparatus shown in FIG. 4A. The semiconductor chip 10A has a feature distinguishable from the semiconductor chip 10 shown in FIG. 1A that the inner ground layer 37A is not overlapped with the signal line 34d and the gap 35 but fully overlapped with the pad 36 in a side of the signal line 34.

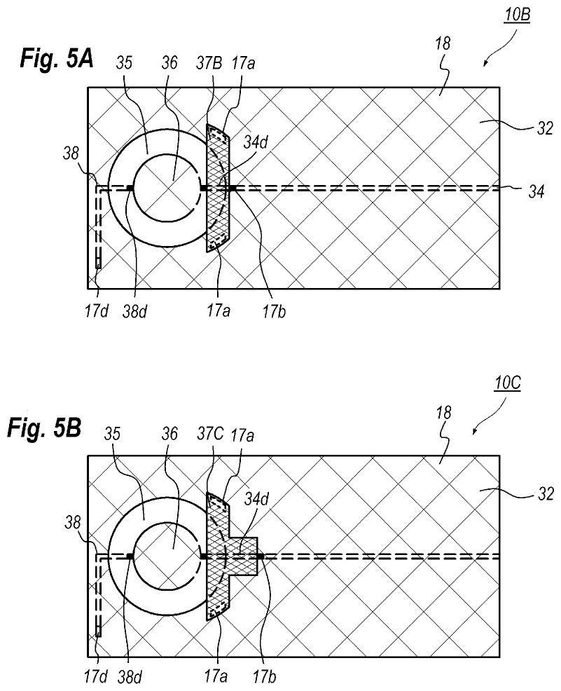

FIGS. 5A and 5B are plan views showing semiconductor chips, 10B and 10C, which are also modified from that shown in FIG. 1A. In FIG. 5A, the inner ground layer 37B is not overlapped with the pad 36 but with the top ground layer 32 beyond the gap 35. The stacked via 17b that connects the signal line 34 in the first metal layer 16b with the signal line 34d in the third metal layer 16d is formed next to the inner ground layer 37B.

The third modification of the inner ground layer 37C is also not overlapped with the pad 36, and has a portion further penetrating under the top ground layer 32. The inner ground layers, 37 to 37C, of the embodiment and the modifications thereof may overlap with the signal line 34d in the portion of the gap 35 and a portion of the pad 36 in the side of the signal line 34d. Those arrangements of the inner ground layers, 37 to 37C, may add capacitive components to the pad 36, and the reflection performance of the pad 36 and the signal lines, 34 and 34d, maybe improved.

### Second Embodiment

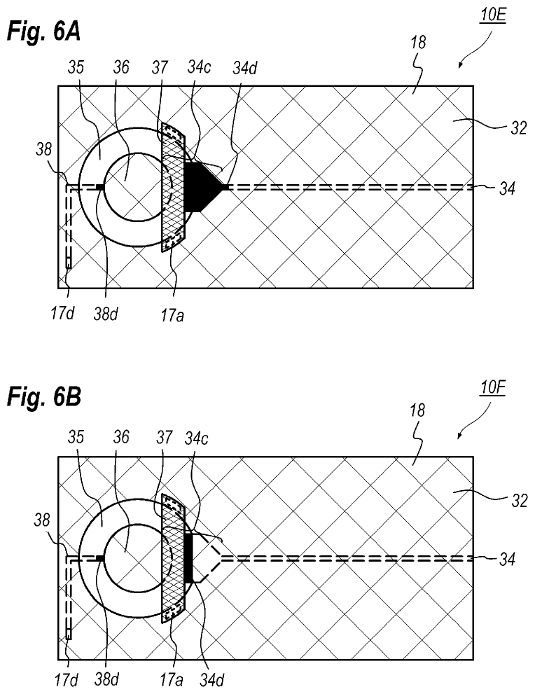

FIGS. 6A and 6B are plan views of the semiconductor chips, 10D and 10E, according to the second embodiment and a modification thereof. The second embodiment has a feature distinguishable from the first embodiment that the signal line 34d in the third metal layer 16d has a portion 34c with an expanded width in a side neighbor to the pad 36. The inner ground layer 37 is substantially same with that of the first embodiment. The widened portion 34c may be formed in the second metal layer 16c. That is, the signal line 34 in the first metal layer 16b is connected with the widened portion 34c in the second metal layer 16c through the first via 16b, and the widened portion 34c in the second metal layer 16c is connected with the signal line 34d through the second via 15c. Because the widened portion 34c is formed in the second metal layer 16c that is same with that of the inner ground layer 37; the inner ground layer 37 and the widened portion 34c are formed in side by side. On the other hand, the arrangement shown in FIG. 6B has a feature that the widened portion 34c is formed in the first metal layer 16b and the stacked via 17b connects the widened portion 34c in the first metal layer 16d with the signal line 34d in the third metal layer 16d.

Thus, the signal line 34 may have a portion overlapped with the top ground layer, where the portion has an expanded width, which may increase capacitance added to the pad 36.

### Third Embodiment

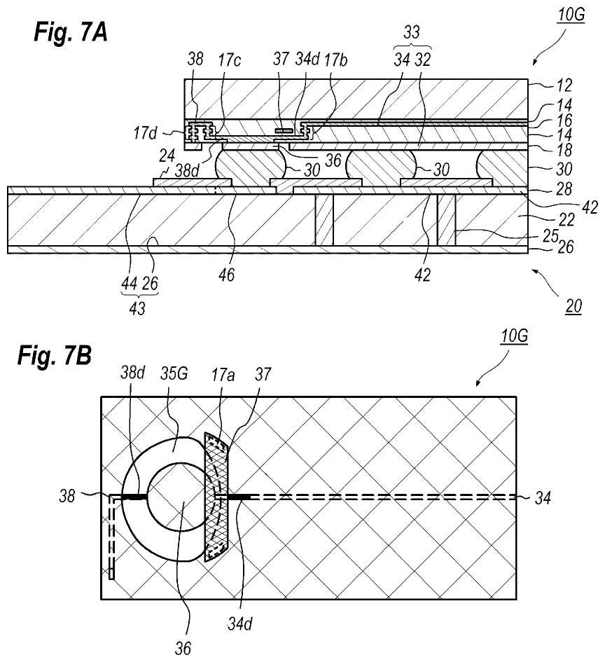

FIG. 7A shows a cross section of an RF apparatus that implements a semiconductor chip 10F according to the third embodiment of the present invention, and FIG. 7B is a plan view showing the semiconductor chip 10F. The semiconductor chip 10F has a feature that the gap 35F has a narrowed portion in a side of the signal line 34d. The inner ground layer 37 has the arrangement same with that of the first embodiment. Because the gap 35F has the narrowed portion, the inner ground layer 37 overlaps with a portion of the pad 36 closer to the signal line 34d, the signal line 34d, and the top ground layer 32. This arrangement of the gap 35F may increase capacitive components to the pad 36.

### Fourth Embodiment

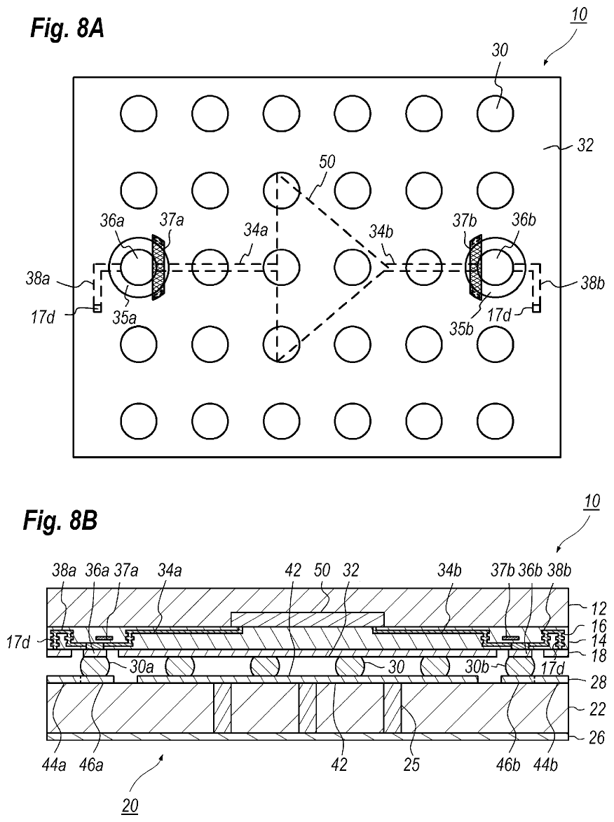

The fourth embodiment of the present invention relates to a monolithic microwave integrated circuit (MMIC) implementing the semiconductor chips, 10 to 10F, described above. FIG. 8A is a plan view showing the semiconductor chip 10 and FIG. 8B shows a cross section of the RF apparatus providing the semiconductor chip 10 and the assembly base 20.

The semiconductor substrate 10 provides a semiconductor active device 50 and signal lines, 34a and 34b, to provide an RF signal to be amplified and to extract an amplified RF signal. The semiconductor active device 50 may be, for instance, a type of high electron mobility transistor (HEMT) having an InGaAs channel layer and an AlGaAs electron supply layer. The semiconductor active device 50 may be, in an alternative, a field effect transistor (FET). The semiconductor substrate 12 may be made of insulating material, such as sapphire, on which a semiconductor active device is formed.

The insulating layer 14 in the top surface thereof provides the top ground layer 32 and two pads, 36a and 36b, electrically isolated from the top ground layer 32 by the gaps, 35a and 35b. The signal lines, 34a and 34b, and the stub lines, 38a and 38b, are extracted from the pads 36a and 36b, along directions opposite to each other. Ends of the stub lines, 38a and 38b, opposite to the pads, 36a and 36b, are connected with the top ground layer 32 through the stacked vias 17d. The stub lines, 38a and 38b, have length shorter than λ/4, where λ is a wavelength of the RF signal subject to the RF apparatus. The inner ground layer, 37a and 37b, overlap with the pads, 36a and 36b, the gaps, 35a and 35b, and the signal lines, 34a and 34b, exactly, portions of the signal lines, 34a and 34b, in the third metal layer 16d. The pad 36a is an input pad to provide the RF signal to the semiconductor active device 50, while, the pad 36b is an output pad to extract the amplified RF signal.

The pad 36a is fixed onto the pad 46a on the assembly base 20 through the bump 30a, while, the pad 36b is connected to the pad 46b also on the assembly base 20 through the bump 30b. The bumps 30, which may be made of solder balls, constitute, what is called, the ball grid array.

Although the RF apparatus of the fourth embodiment shown in FIGS. 8A and 8B provides the stub liens, 38a and 38b, and the inner ground layers, 37a and 37b, in both pads, 36a and 36b; the RF apparatus may provide the stub line and the inner ground layer only one of the pads. The stub lines, 38a and 38b, and the inner ground layers, 37a and 37b, may suppress the reflection of the RF signals, in particular, the inner ground lines, 37a and 37b, may suppress the reflection at frequencies exceeding 80 GHz.

The bumps, 30a and 30b, mounted of the pads, 36a and 36b, increase capacitive components against the top ground layer 32, which enhances the reflection of the RF signal. The inner ground layers, 37a and 37b, and the short stubs, 36a and 36b, may effectively suppress the reflection of the RF signal.

While particular embodiment of the present invention have been described herein for purposes of illustration, further modifications and changes will become apparent to those skilled in the art. Accordingly, the appended claims are intended to encompass all such modifications and changes as fall within the true spirit and scope of this invention.

The present application claims the benefit of priority of Japanese Patent Application No. 2016-213399, filed on Oct. 31, 2016, which is incorporated herein by reference.

1-16. (canceled)

17. The semiconductor chip according to claim 19,
wherein the inner ground layer overlaps with a part of the pad.

18. The semiconductor chip according to claim 19,
wherein the signal line has a part in the first metal layer and another part in the third metal layer, the part being connected to the semiconductor active device, the another part being connected to the pad,
wherein the sub line has a part in the first metal layer and another part in the third metal layer that is connected to the pad, and
wherein the inner ground layer is provided in the second metal layer.

19. A semiconductor chip for amplifying a radio frequency (RF) signal, comprising:
a semiconductor substrate that provides a semiconductor active device therein,
first, second, and third metal layers stacked on the semiconductor substrate in this order, included in a plurality of insulating layers, and electrically isolated from each other by an insulating layer of the plurality of insulating layers,
a top metal layer further provided on a top surface of the plurality of insulating layers, the top metal layer including a top ground layer and a pad that is formed within the top ground layer by a gap and electrically isolated from the top ground layer by the gap, the pad being connected to the assembly base through a solder ball of the ball grid array,
a signal line included in the first and the third metal layers that electrically connects the semiconductor active device to the pad,
a stub line that is included in the first metal layer and that is electrically connected to the pad, the stub line having a length shorter than λ/4, where λ is a wavelength subject to the RF signal, and
an inner ground layer that is included in the second metal layer and that, in a plan view, overlaps with the gap between the pad and the top ground layer.
